(19) United States
(12) Patent Application Publication
(10) Pub. No.: US 2006/0195731 A1
(43) Pub. Date: Aug. 31, 2006

(54) First failure data capture based on threshold violation

(75) Inventors: Bret Patterson, Cedar Park, TX (US); John Richards Rowland, Coupland, TX (US); Kirk Malcolm Sexton, Austin, TX (US)

Correspondence Address: IBM CORP (YA);C/O YEE & ASSOCIATES PC, P.O. BOX 802333, DALLAS, TX, 75380, US

(73) Assignee: International Business Machines Corporation, Armonk, NY (US)

(21) Appl. No.: 11/060,611

(22) Filed: Feb. 17, 2005

(51) Int. Cl. G11C 29/00

(52) U.S. Cl. 714/723

(57) ABSTRACT

A first failure data capture mechanism receives threshold violation events. The end user may configure which threshold violations would trigger first failure data capture. A correlator may be used to select only the related log and trade data to fit the specific application. When a predetermined threshold violation event is received, the first failure data capture mechanism gathers the appropriate log information. The first failure data capture mechanism may also query for other information related to the transaction that caused the threshold violation.

### BACKGROUND OF THE INVENTION

1. Technical Field

The present invention relates to data processing and, in particular, to error logs and data capture. Still more particularly, the present invention provides a method, apparatus, and program for first failure data capture based on threshold violation.

2. Description of Related Art

Monitoring and correlating transactions is an excellent way to provide detailed performance statistics and a high level view of where errors occur. One example of a monitoring and correlating system is the IBM Tivoli® Monitoring for Transaction Performance software which is a centrally managed suite of software components that monitor the availability and performance of Web-based services and Microsoft Windows® applications. IBM Tivoli® Monitoring for Transaction Performance (ITMTP) captures detailed performance data for all e-business transactions. The software may be used to perform the following e-business management tasks:
Monitor every step of an actual customer transaction as it passes through a complex array of hosts, systems, and applications: Web and proxy servers, Web application servers, database management systems, and legacy back-office systems and applications.
Simulate customer transactions, collecting performance data that helps in assessing the health of e-business components and configurations.
Consult comprehensive real-time reports that display recently collected data in a variety of formats and from a variety of perspectives. Integrate with the IBM Tivoli® Data Warehouse, where collected data may be stored for use in historical analysis and long-term planning.
Receive prompt, automated notification of performance problems, which provides accurate measurements of how users experience your Web site and applications under different conditions and at different times. Most importantly, performance problems may be isolated at the source as they occur, so that the problems may be corrected before they produce expensive outages and lost revenue.

Applications may use IBM Tivoli® Monitoring for Transaction Performance to measure transaction response times through the IBM Tivoli® Application Response Measurement (ARM) Application Program Interface (API). In order to use ARM, applications must be modified to call the ARM API at the defined business transaction boundaries. This modification may be accomplished at runtime using automatic instrumentation of code, although it is also possible to manually instrument code to call the ARM API. ARM instrumented applications may use the IBM Tivoli® Monitoring for Transaction Performance console to visualize transaction topology, define thresholds for transactions, and receive alerts when transaction thresholds are violated.

Integrated applications may take advantage of the following major components that may be used to investigate and monitor transactions:
Discovery component allows identification of incoming Web transactions that need to be monitored.
Listening components are the quality of service and J2EE monitoring components that collect data for actual user transactions that are executed against the Web servers and Web applications servers.
Playback components are synthetic transaction investigator and Rational robot/generic Windows that robotically execute, or playback, transactions that are recorded in order to simulate actual user activity.

Although the IBM Tivoli® Monitoring for Transaction Performance captures detailed performance data for all e-business transactions, a problem may exist in that the log files provide only a general idea of how to solve the problem. The extensive log files that are created for the e-business transactions require an extensive review of all of the logged transactions and the related code to determine where and when an error occurs and what part of the code caused the error. This operation may be time consuming and possibly prone to further error. Thus, providing additional trace logs or log statements would assist in determining the location and time of the transaction instance where the error occurred, and, in turn, the related portion of code that was accessed during the transaction.

First failure data capture (FFDC) is the automatic collection of serviceability data, such as logs, trace files, dumps, snapshots, etc., based on some event or user action. This gathered information reduces the need to reproduce significant errors to determine diagnostic information to determine a cause. FFDC may be triggered by a list of message identifications (IDs). If a given error is logged or an exception occurs, then FFDC will occur. However, these approaches are not useful in cases where the performance is unacceptable, but no exception or error message occurs.

### SUMMARY OF THE INVENTION

The present invention recognizes the disadvantages of the prior art and provides first failure data capture based on threshold violation. An application monitor determines whether a threshold violation occurs. The end user may configure which threshold violations would trigger first failure data capture. A correlator may be used to select only the related log and trace data to fit the specific application. When a predetermined threshold violation event occurs, the first failure data capture mechanism gathers the appropriate log information. The first failure data capture mechanism may also query for other information related to the transaction that caused the threshold violation.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 is a pictorial representation of a network of data processing systems in which the present invention may be implemented;

FIG. 2 is a block diagram of a data processing system that may be implemented as a server in accordance with an exemplary embodiment of the present invention;

FIG. 3 is a block diagram of a data processing system in which the present invention may be implemented;

FIG. 4 is a block diagram of an application monitoring environment in which the present invention may be implemented; and

FIG. 5 is a flowchart illustrating operation of an application monitor in accordance with an exemplary embodiment of the present invention.

### DETAILED DESCRIPTION OF THE PREFERRED EMBODIMENT

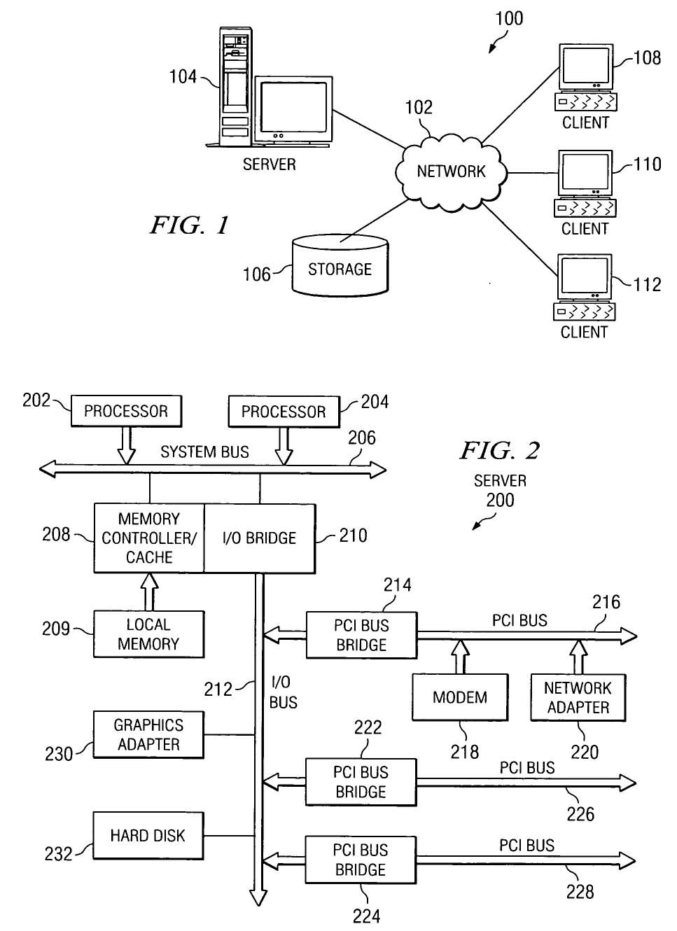

The present invention provides a method, apparatus and computer instructions for first failure data capture based on threshold violation. The data processing device may be a stand-alone computing device or may be a distributed data processing system in which multiple computing devices are utilized to perform various aspects of the present invention. Therefore, the following FIGS. 1-3 are provided as exemplary diagrams of data processing environments in which the present invention may be implemented. It should be appreciated that FIGS. 1-3 are only exemplary and are not intended to assert or imply any limitation with regard to the environments in which the present invention may be implemented. Many modifications to the depicted environments may be made without departing from the spirit and scope of the present invention.

With reference now to the figures, FIG. 1 depicts a pictorial representation of a network of data processing systems in which the present invention may be implemented. Network data processing system 100 is a network of computers in which the present invention may be implemented. Network data processing system 100 contains a network 102, which is the medium used to provide communications links between various devices and computers connected together within network data processing system 100. Network 102 may include connections, such as wire, wireless communication links, or fiber optic cables.

In the depicted example, server 104 is connected to network 102 along with storage unit 106. In addition, clients 108, 110, and 112 are connected to network 102. These clients 108, 110, and 112 may be, for example, personal computers or network computers. In the depicted example, server 104 provides data, such as boot files, operating system images, and applications to clients 108-112. Clients 108, 110, and 112 are clients to server 104. Network data processing system 100 may include additional servers, clients, and other devices not shown.

In accordance with a preferred embodiment of the present invention, server 104 provides application integration tools to application developers for applications that are used on clients 108, 110, 112. More particularly, server 104 may provide access to application integration tools that will allow two different front-end applications in two different formats to disseminate messages sent from each other.

In accordance with one preferred embodiment, a dynamic framework is provided for using a graphical user interface (GUI) for configuring business system management software. This framework involves the development of user interface (UI) components for business elements in the configuration of the business system management software, which may exist on storage 106. This framework may be provided through an editor mechanism on server 104 in the depicted example. The UI components and business elements may be accessed, for example, using a browser client application on one of clients 108, 110, 112.

In the depicted example, network data processing system 100 is the Internet with network 102 representing a worldwide collection of networks and gateways that use the Transmission Control Protocol/Internet Protocol (TCP/IP) suite of protocols to communicate with one another. At the heart of the Internet is a backbone of high-speed data communication lines between major nodes or host computers, consisting of thousands of commercial, government, educational and other computer systems that route data and messages. Of course, network data processing system 100 also may be implemented as a number of different types of networks, such as for example, an intranet, a local area network (LAN), or a wide area network (WAN). FIG. 1 is intended as an example, and not as an architectural limitation for the present invention.

Referring to FIG. 2, a block diagram of a data processing system that may be implemented as a server, such as server 104 in FIG. 1, is depicted in accordance with a preferred embodiment of the present invention. Data processing system 200 may be a symmetric multiprocessor (SMP) system including a plurality of processors 202 and 204 connected to system bus 206. Alternatively, a single processor system may be employed. Also connected to system bus 206 is memory controller/cache 208, which provides an interface to local memory 209. I/O bus bridge 210 is connected to system bus 206 and provides an interface to I/O bus 212. Memory controller/cache 208 and I/O bus bridge 210 may be integrated as depicted.

Peripheral component interconnect (PCI) bus bridge 214 connected to I/O bus 212 provides an interface to PCI local bus 216. A number of modems may be connected to PCI local bus 216. Typical PCI bus implementations will support four PCI expansion slots or add-in connectors. Communications links to clients 108-112 in FIG. 1 may be provided through modem 218 and network adapter 220 connected to PCI local bus 216 through add-in connectors.

Additional PCI bus bridges 222 and 224 provide interfaces for additional PCI local buses 226 and 228, from which additional modems or network adapters may be supported. In this manner, data processing system 200 allows connections to multiple network computers. A memory-mapped graphics adapter 230 and hard disk 232 may also be connected to I/O bus 212 as depicted, either directly or indirectly.

Those of ordinary skill in the art will appreciate that the hardware depicted in FIG. 2 may vary. For example, other peripheral devices, such as optical disk drives and the like, also may be used in addition to or in place of the hardware depicted. The depicted example is not meant to imply architectural limitations with respect to the present invention.

The data processing system depicted in FIG. 2 may be, for example, an IBM eServer™ pSeries® system, a product of International Business Machines Corporation in Armonk, N.Y., running the Advanced Interactive Executive (AIX™) operating system or LINUX operating system.

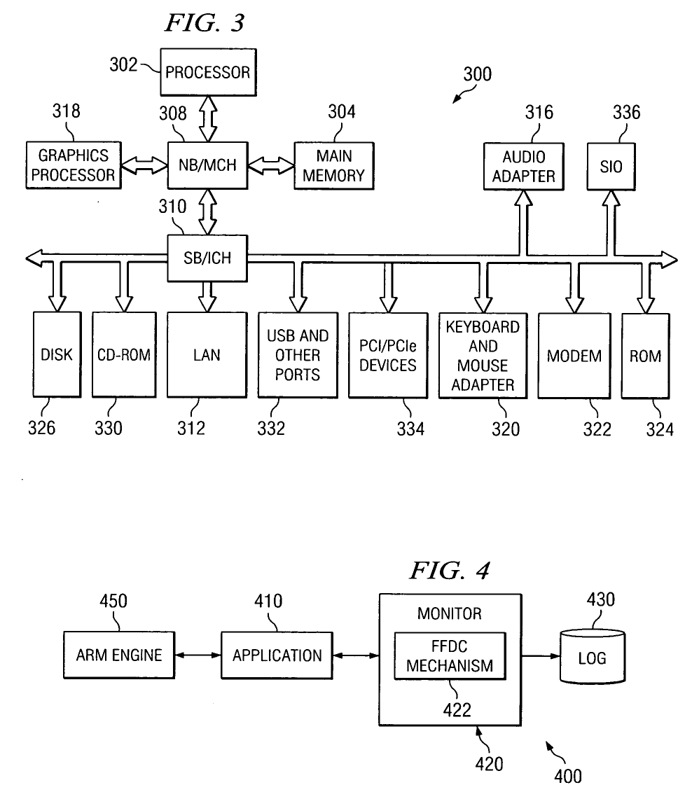

With reference now to FIG. 3, a block diagram of a data processing system is shown in which the present invention may be implemented. Data processing system 300 is an example of a computer, such as client 108 in FIG. 1, in which code or instructions implementing the processes of the present invention may be located. In the depicted example, data processing system 300 employs a hub architecture including a north bridge and memory controller hub (MCH) 308 and a south bridge and input/output (I/O) controller hub (ICH) 310. Processor 302, main memory 304, and graphics processor 318 are connected to MCH 308. Graphics processor 318 may be connected to the MCH through an accelerated graphics port (AGP), for example.

In the depicted example, local area network (LAN) adapter 312, audio adapter 316, keyboard and mouse adapter 320, modem 322, read only memory (ROM) 324, hard disk drive (HDD) 326, CD-ROM driver 330, universal serial bus (USB) ports and other communications ports 332, and PCI/PCIe devices 334 may be connected to ICH 310. PCI/PCIe devices may include, for example, Ethernet adapters, add-in cards, PC cards for notebook computers, etc. PCI uses a cardbus controller, while PCIe does not. ROM 324 may be, for example, a flash binary input/output system (BIOS). Hard disk drive 326 and CD-ROM drive 330 may use, for example, an integrated drive electronics (IDE) or serial advanced technology attachment (SATA) interface. A super I/O (SIO) device 336 may be connected to ICH 310.

An operating system runs on processor 302 and is used to coordinate and provide control of various components within data processing system 300 in FIG. 3. The operating system may be a commercially available operating system such as Windows XP™, which is available from Microsoft Corporation. An object oriented programming system, such as the Java™ programming system, may run in conjunction with the operating system and provides calls to the operating system from Java™ programs or applications executing on data processing system 300. “JAVA” is a trademark of Sun Microsystems, Inc.

Instructions for the operating system, the object-oriented programming system, and applications or programs are located on storage devices, such as hard disk drive 326, and may be loaded into main memory 304 for execution by processor 302. The processes of the present invention are performed by processor 302 using computer implemented instructions, which may be located in a memory such as, for example, main memory 304, memory 324, or in one or more peripheral devices 326 and 330.

Those of ordinary skill in the art will appreciate that the hardware in FIG. 3 may vary depending on the implementation. Other internal hardware or peripheral devices, such as flash memory, equivalent non-volatile memory, or optical disk drives and the like, may be used in addition to or in place of the hardware depicted in FIG. 3. Also, the processes of the present invention may be applied to a multiprocessor data processing system.

For example, data processing system 300 may be a personal digital assistant (PDA), which is configured with flash memory to provide non-volatile memory for storing operating system files and/or user-generated data. The depicted example in FIG. 3 and above-described examples are not meant to imply architectural limitations. For example, data processing system 300 also may be a tablet computer, laptop computer, or telephone device in addition to taking the form of a PDA.

With reference now to FIG. 4, a block diagram of an application monitoring environment is shown in which the present invention may be implemented. In exemplary data processing system 400, application 410 generates messages that are monitored by monitor 420. Monitor 420 stores message logs, trace files, dumps, snapshots, and the like to log storage 430. The logs, traces, and the like may be stored in a predefined directory, for example, so an administrator may easily find and examine the information.

Monitor 420 includes first failure data capture (FFDC) mechanism 422, which receives error messages and/or exceptions from application 410. In response to a predefined error message, such as a significant error condition, or an exception, FFDC mechanism 422 gathers appropriate log information from log storage 430 for output. For example, FFDC mechanism 422 may store a list of message IDs that trigger an FFDC. FFDC mechanism 422 may output the log information to a printer, a separate storage location, or a user terminal. An administrator may then review the log information to determine a cause of the significant error or exception without having to recreate the failure.

In accordance with a preferred embodiment of the present invention, application 410 has ARM engine 450 instrumented. Through ARM engine 450, application 410 sends error messages, other messages, and exceptions to monitor 420. Application monitor 420 may then determine whether a threshold violation occurs. Threshold violations may occur, for example, when a field violates a predefined threshold. For example, an application may access a database. If a database access takes more than a half a second, for example, then a threshold violation event may be generated. An administrator or other user watching the operation of an application, particularly the performance of an application, may predefine the thresholds for threshold violation events. The application itself may not have any awareness that it is being monitored or that there is a threshold.

An ARM start call is sent from application 410 to ARM engine 450. ARM engine 450 responds to the ARM start call from application 410 with a correlator. A correlator indicates a correlation between two lines of execution, perhaps on different machines. For example, if a first thread starts a second thread, the first thread makes an ARM start call to ARM engine 450 for a correlator. ARM engine 450 keeps timing values for all of the bits and pieces, i.e. subtransactions, of a transaction and then puts those subtransactions together for an overall execution time, making use of the correlators to do so. When a transaction or subtransaction completes, the application sends an ARM stop call to ARM engine 450.

Messages are sent from application 410 to monitor 420 and these messages may include correlators. Monitor 420 may then use the correlators to determine whether a threshold violation occurs. For example, when a subtransaction completes, monitor 420 may determine that the subtransaction took too much time and, thus, violated a threshold. Monitor 420 may query ARM engine 450 to determine other correlators that are related to a given correlator. Therefore, a group of subtransactions may not violate a threshold but when the subtransactions are put together to for an overall transaction, using ARM engine 450 and the resulting correlators, the overall transaction could violate a threshold.

Correlators generated by ARM engine 450 may also be used by monitor 420 to set logging levels so that only the related log and trace data is logged. This is described in more detail in related application entitled “USING ARM CORRELATORS TO LINK LOG FILE STATEMENTS TO TRANSACTION INSTANCES AND DYNAMICALLY ADJUSTING LOG LEVELS IN RESPONSE TO THRESHOLD VIOLATIONS,” U.S. patent application Ser. No. ______, (Docket Number AUS920040771US1), filed on and herein incorporated by reference.

Responsive to a threshold violation, FFDC mechanism 422 gathers the appropriate log information from log storage 430. Thus, FFDC mechanism 422 may perform a FFDC in a situation in which the customer is most interested: the case where performance is not acceptable. A threshold violation may indicate that the application is performing at an unacceptable level. An administrator may then review the log information to determine a cause of the unacceptable performance without having to recreate the situation.

FFDC mechanism 422 may gather only messages that are related to a specific correlator. FFDC mechanism 422 may also query ARM engine 450 to determine other correlators that are related to a given correlator. FFDC mechanism 422 may then output log information related to a given correlator and all related correlators.

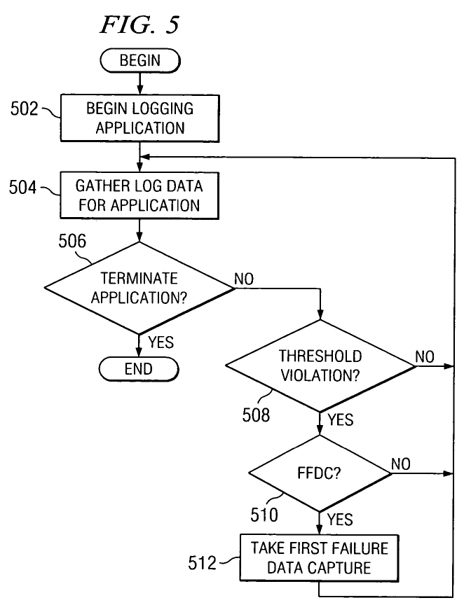

FIG. 5 is a flowchart illustrating operation of an application monitor in accordance with an exemplary embodiment of the present invention. Operation begins and the monitor beings logging an application (block 502). The monitor then gathers log data for the application (block 504). Log data may include, for example, message logs, trace files, dumps, snapshots, and the like. The monitor may simply log messages generated by the application; however, the application may use an ARM engine to adjust log levels to select only related log and trace data to fit a customer's implementation.

Next, a determination is made as to whether the application terminates (block 506). If the application terminates, operation ends. If the application does not terminate in block 506, a determination is made as to whether a threshold violation occurs (block 508). If the application instruments an ARM engine, then a correlator may be used by the application monitor to determine whether a threshold violation occurs and, if so, whether a threshold violation triggers the collection of current logs and traces in an application monitor.

If a threshold violation event does not occur, operation returns to block 504 to gather log data for the application. If a threshold violation occurs in block 508, a first failure data capture mechanism determines whether a first failure data capture is to be taken for the threshold violation (block 510). If a first failure data capture is to be taken, the first failure data capture mechanism automatically collects serviceability data from the log data (block 512). Thereafter, operation returns to block 504 to gather log data for the application. If, however, a first failure data capture is not to be taken for the threshold violation in block 510, operation returns to block 504 to gather log data for the application

Thus, the present invention solves the disadvantages of the prior art by providing a first failure data capture mechanism determines whether to capture log data based on threshold violation events. The end user may configure which threshold violations would trigger first failure data capture. A correlator may be used to select only the related log and trace data to fit the specific application. When a predetermined threshold violation occurs, the first failure data capture mechanism gathers the appropriate log information. The first failure data capture mechanism may also query for other information related to the transaction that caused the threshold violation, such as a uniform resource locator (URL) being accessed at the time of the threshold violation. The first failure data capture mechanism of the present invention allows data capture to be triggered by unacceptable performance, rather than an error or exception. This allows an administrator to improve performance, which is of particular importance to customers.

It is important to note that while the present invention has been described in the context of a fully functioning data processing system, those of ordinary skill in the art will appreciate that the processes of the present invention are capable of being distributed in the form of a computer readable medium of instructions and a variety of forms and that the present invention applies equally regardless of the particular type of signal bearing media actually used to carry out the distribution. Examples of computer readable media include recordable-type media, such as a floppy disk, a hard disk drive, a RAM, CD-ROMs, DVD-ROMs, and transmission-type media, such as digital and analog communications links, wired or wireless communications links using transmission forms, such as, for example, radio frequency and light wave transmissions. The computer readable media may take the form of coded formats that are decoded for actual use in a particular data processing system.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A method for monitoring an application, the method comprising:
collecting, at an application monitor, log data for an application;
determining, at an application monitor, whether a threshold violation occurs in the application;
responsive to a determination that a threshold violation occurs, determining whether the threshold violation triggers a first failure data capture; and
if the threshold violation triggers a first failure data capture, outputting at least a portion of the log data.

2. The method of claim 1, wherein the log data includes at least one of message logs, trace files, dumps, and snapshots.

3. The method of claim 1, wherein the application instruments an application response measurement application programming interface.

4. The method of claim 3, further comprising:
receiving, at the application, a correlator from the application response measurement application programming interface; and
sending a message from the application to the application monitor, wherein the message includes the correlator and wherein the correlator is used by the application monitor to determine whether a threshold violation occurs.

5. The method of claim 4, wherein the correlator is used by the application monitor to determine the portion of the log data to output.

6. The method of claim 4, wherein the correlator is a current correlator, the method further comprising:
querying, by the application monitor, the application response measurement application programming interface for correlators related to the current correlator.

7. The method of claim 1, wherein outputting at least a portion of the log data includes outputting the portion of the log data to one of a printer, a separate storage location, and a user terminal.

8. An apparatus for monitoring an application, the apparatus comprising:
an application that is to be monitored;
an application monitor that collects log data for the application and determines whether a threshold violation occurs in the application; and
a first failure data capture mechanism that, responsive to a determination that a threshold violation occurs, determines whether the threshold violation triggers a first failure data capture and, if the threshold violation triggers a first failure data capture, outputs at least a portion of the log data.

9. The apparatus of claim 8, wherein the log data includes at least one of message logs, trace files, dumps, and snapshots.

10. The apparatus of claim 8, wherein the application instruments an application response measurement application programming interface.

11. The apparatus of claim 10, wherein the application receives a correlator from the application response measurement application programming interface and sends a message to the application monitor, wherein the message includes the correlator, and wherein the correlator is used by the application monitor to determine whether a threshold violation occurs.

12. The apparatus of claim 11, wherein the correlator is used by the application monitor to determine the portion of the log data to output.

13. The apparatus of claim 11, wherein the correlator is a current correlator and wherein the application monitor queries the application response measurement application programming interface for correlators related to the current correlator.

14. The apparatus of claim 8, wherein the first failure data capture mechanism outputs the portion of the log data to one of a printer, a separate storage location, and a user terminal.

15. A computer program product, in a computer readable medium, for monitoring an application, the computer program product comprising:
instructions for collecting, at an application monitor, log data for an application;
instructions for determining, at an application monitor, whether a threshold violation occurs in the application;
instructions, responsive to a determination that a threshold violation occurs, for determining whether the threshold violation triggers a first failure data capture; and
instructions for comprising at least a portion of the log data if the threshold violation triggers a first failure data capture.

16. The computer program product of claim 15, wherein the log data includes at least one of message logs, trace files, dumps, and snapshots.

17. The computer program product of claim 15, wherein the application instruments an application response measurement application programming interface.

18. The computer program product of claim 17, further comprising:
instructions for receiving, at the application, a correlator from the application response measurement application programming interface; and
instructions for sending a message from the application to the application monitor, wherein the message includes the correlator and wherein the correlator is used by the application monitor to determine whether a threshold violation occurs.

19. The computer program product of claim 18, wherein the correlator is used by the application monitor to determine the portion of the log data to output.

20. The computer program product of claim 15, wherein outputting at least a portion of the log data includes outputting the portion of the log data to one of a printer, a separate storage location, and a user terminal.
